(19) United States
(12) Patent Application Publication
(10) Pub. No.: US 2025/0335007 A1
(43) Pub. Date: Oct. 30, 2025

(54) DISPLAY DEVICE

(71) Applicant: Samsung Display Co., LTD., Yongin-si (KR)

(72) Inventors: YOUNGJE CHO, Yongin-si (KR); SANGHYUN HAN, Yongin-si (KR)

(21) Appl. No.: 19/065,485

(22) Filed: Feb. 27, 2025

(30) Foreign Application Priority Data
Apr. 30, 2024 (KR) 10-2024-0057525

(51) Int. Cl. G06F 1/16; H10K 77/10; H10K 102/00

(52) U.S. Cl. CPC G06F 1/1652; H10K 77/111; H10K 2102/311

(57) ABSTRACT

An electronic device includes a display module including an electronic panel, and a protective member disposed on an upper portion or a lower portion of the electronic panel, which are opposite to each other, and a rolling shaft extending in a first direction in a way such that the display module is rolled thereon, wherein a stepped portion, to which a side surface of the display module is coupled, is defined in the rolling shaft. The protective member includes protective patterns each extending along the first direction and spaced apart from each other along a second direction crossing the first direction in a plan view, and a protective layer covering the electronic panel and the protective patterns, and at least one selected from the protective patterns overlaps the stepped portion in a state, in which the display module is rolled on the rolling shaft.

This application claims priority to Korean Patent Application No. 10-2024-0057525, filed on Apr. 30, 2024, and all the benefits accruing therefrom under 35 U.S.C. § 119, the content of which in its entirety is herein incorporated by reference.

### BACKGROUND

### (1) Field

Embodiments of the disclosure described herein relate to a rollable display device.

### (2) Description of the Related Art

Electronic devices, such as smart phones, digital cameras, laptop computers, navigation systems, and smart televisions, which provide images to users may include display devices for displaying images. A display device generates an image, and provides the image to the user through a display screen.

Recently, with the development of display device technology, various types of display devices are being developed. For example, various types of flexible display devices that may be deformed into curved shapes, folded, or rolled are being developed. Flexible display devices are easy to carry and may improve convenience of the user.

Among flexible display devices, a rollable display device typically includes a display module, a rolling shaft, on which the display module is wound, and a housing that accommodates the display module and the rolling shaft, on which the display module is wound. As a roller is rotated, the display module may be extracted to an outside of a housing or inserted into the housing.

### SUMMARY

Embodiments of the disclosure provide a display device including an electronic panel, in which wrinkles generated during rolling are substantially reduced or effectively prevented.

According to an embodiment, an electronic device includes a display module including an electronic panel, and a protective member disposed on an upper portion or a lower portion of the electronic panel, which are opposite to each other, and a rolling shaft extending in a first direction in a way such that the display module is rolled thereon, where a stepped portion, to which a side surface of the display module is coupled, is defined in the rolling shaft, where the protective member includes protective patterns each extending along the first direction and spaced apart from each other along a second direction crossing the first direction in a plan view, and a protective layer covering the electronic panel and the protective patterns, and at least one selected from the protective patterns overlaps the stepped portion in a state, in which the display module is rolled on the rolling shaft.

In an embodiment, a modulus of the protective patterns and a modulus of the protective layer may be different from each other.

In an embodiment, the modulus of the protective patterns may be in a range of about 3 gigapascals (GPa) to about 20 GPa, and the modulus of the protective layer may be in a range of about 0.5 GPa to about 2.5 GPa.

In an embodiment, the protective patterns may include a polyhedral oligomeric silsesquioxane-based material, and the protective layer may include an acrylic-based material.

In an embodiment, a thickness of the protective patterns may be in a range of about 1 micrometer (μm) to 50 μm, and a thickness of the protective layer may be in a range of about 10 μm to about 100 μm.

In an embodiment, a width of the protective patterns may be in a range of about 20 millimeters (mm) to about 60 mm.

In an embodiment, the rolling shaft may include a first circular arc being a curve from about zero (0) degree to a reference angle with respect to a central point of the rolling shaft, and a second circular arc being a curve from the reference angle to about 360 degrees with respect to the central point, on a cross-section being perpendicular to the first direction, the first circular arc may have a first radius varying with respect to the central point, the second circular arc may have a constant second radius with respect to the central point, and the stepped portion may be defined by a difference between the second radius at about 360 degrees and the first radius at about zero (0) degree.

In an embodiment, the difference between the second radius at about 360 degrees and the first radius at about zero (0) degree may be the same as a thickness of the side surface of the display module.

In an embodiment, the protective member may be disposed on the upper portion of the electronic panel, and the protective patterns and the protective layer may contact the upper portion.

In an embodiment, the electronic device may further include a lower protective member contacting the lower portion of the electronic panel, and including a same material as a material of the protective layer.

In an embodiment, the electronic device may further include a lower protective member disposed on the lower portion of the electronic panel, where the lower protective member may include lower protective patterns each extending along the first direction and spaced apart from each other along a second direction crossing the first direction in the plan view, and a lower protective layer covering the lower protective patterns and the lower portion, where the lower protective patterns may overlap the protective patterns.

In an embodiment, a thickness of the protective patterns may be less than a thickness of the lower protective patterns.

In an embodiment, a width of the protective patterns may be greater than a width of the lower protective patterns.

In an embodiment, the protective patterns may have a shape convex from the lower portion in a direction facing the upper portion, and the lower protective patterns may have a shape convex from the upper portion in a direction facing the lower portion, on a cross-section.

In an embodiment, the protective patterns may include a first pattern adjacent to the side surface of the display module and a second pattern spaced apart from the side surface of the display module further than the first pattern, and a width of the second pattern may be greater than a width of the first pattern.

In an embodiment, the protective patterns may be disposed in an interior of the protective layer not to contact the electronic panel.

In an embodiment, each of the protective patterns may include patterns extending in the first direction and spaced apart from each other along the second direction in the plan view, and a portion of the protective layer may be disposed between adjacent ones of the patterns along the second direction.

In an embodiment, the protective patterns and the protective layer may contact the lower portion of the electronic panel.

In an embodiment, the electronic device may further include an upper protective member contacting an upper portion opposite to the lower portion, where the upper protective member includes a same material as a material of the protective layer.

In an embodiment, the electronic device may further include a panel support layer disposed on the lower portion of the electronic panel, the panel support layer may include a support layer, and support bars each extending along the first direction, and spaced apart from each other along the second direction in the plan view, and the support bars may be disposed in an interior of the support layer.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of a display device in an unrolled state according to an embodiment of the disclosure.

FIG. 2 is a perspective view of a display device in a rolled state according to an embodiment of the disclosure.

FIG. 3 is a cross-sectional view of a display module according to an embodiment of the disclosure.

FIG. 4 is a perspective view of a panel support layer according to an embodiment of the disclosure.

FIG. 5 is a cross-sectional view of an electronic panel according to an embodiment of the disclosure.

FIG. 6 is a cross-sectional view of a display panel according to an embodiment of the disclosure.

FIG. 7 is a cross-sectional view of a rolling shaft and an unrolled electronic panel according to an embodiment of the disclosure.

FIG. 8 is a cross-sectional view of a rolling shaft and a rolled electronic panel according to an embodiment of the disclosure.

FIG. 9 is a plan view of a protective member according to an embodiment of the disclosure.

FIG. 10 is a cross-sectional view of an electronic panel in an unrolled state according to an embodiment of the disclosure.

FIG. 11 is a cross-sectional view of an electronic panel in an unrolled state according to an embodiment of the disclosure.

FIG. 12 is a cross-sectional view of an electronic panel in an unrolled state according to an embodiment of the disclosure.

FIG. 13 is a cross-sectional view of an electronic panel in an unrolled state according to an embodiment of the disclosure.

FIG. 14 is a cross-sectional view of an electronic panel in an unrolled state according to an embodiment of the disclosure.

FIG. 15 is a cross-sectional view of an electronic panel in an unrolled state according to an embodiment of the disclosure.

FIG. 16 is a cross-sectional view of an electronic panel in an unrolled state according to an embodiment of the disclosure.

FIG. 17 is a cross-sectional view of an electronic panel in an unrolled state according to an embodiment of the disclosure.

FIG. 18 is a cross-sectional view of an electronic panel in an unrolled state according to an embodiment of the disclosure.

FIG. 19 is a cross-sectional view of an electronic panel in an unrolled state according to an embodiment of the disclosure.

FIG. 20 is a cross-sectional view of an electronic panel in an unrolled state according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the specification, when it is mentioned that a component (or an area, a layer, a part, or the like) is “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms, including technical and scientific terms, used herein have the same meaning as commonly understood by those skilled in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

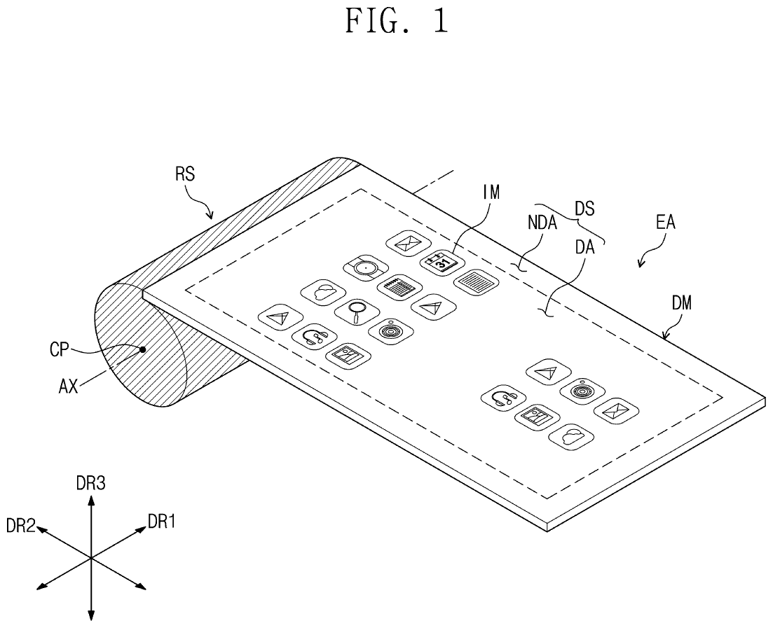

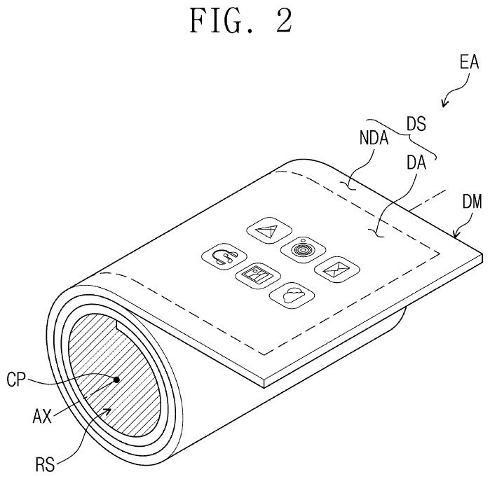

FIG. 1 is a perspective view of a display device in an unrolled state according to an embodiment of the disclosure. FIG. 2 is a perspective view of a display device in a rolled state according to an embodiment of the disclosure.

Referring to FIGS. 1 and 2, a display device EA according to an embodiment may include a display module DM and a rolling shaft RS. The display module DM may be a rollable panel, a portion of which is coupled to the rolling shaft RS and which is rolled with respect to the rolling shaft RS. The display device EA according to an embodiment may include a housing that may accommodate the display module DM and the rolling shaft RS. An opening that exposes a portion of the display module DM may be defined in the housing. In a state, in which the display module DM is completely rolled on the rolling shaft RS, the display module DM may not be exposed to an outside of the housing, and a portion of the display module DM, which is loosened from the rolling shaft RS, may be exposed to an outside through the opening. Then, the portion of the display module DM, which is exposed to the outside, may display an image IM. In FIG. 1, an icon is illustrated as an example of the image IM. The image IM may include a static image as well as a dynamic image.

The display module DM that is unrolled from the rolling shaft RS may have a plane that is defined by first and second directions DR1 and DR2. The display module DM may have a rectangular shape having long sides that extend in the second direction DR2 and short sides that extend in the first direction DR1 in a plan view or when viewed in the third direction DR3. However, the disclosure is not limited thereto, and the display module DM may have various shapes, such as a circular shape or a polygonal shape in a plan view or when viewed in the third direction DR3. Here, the third direction DR3 may be a direction perpendicular to the first and second directions DR1 and DR2, or a thickness direction of the display module DM in a state of being unrolled from the rolling shaft RS.

An upper portion of the display module DM may be defined as a display surface DS, and may have a plane that is defined by the first direction DR1 and the second direction DR2. The image IM generated in the display module DM may be provided to the user through the display surface DS.

The display surface DS may include a display area DA and a non-display area NDA around the display area DA. The display area DA may display an image, and the non-display area NDA may not display an image. The non-display area NDA surrounds the display area DA, and may define a periphery of the display module DM, which is printed in a specific color.

The display module DM may be a flexible display module that may be rolled on the rolling shaft RS. The display module DM may be rolled or unrolled in the second direction DR2. The display module DM may be rolled in a way such that the display surface DS faces the outside of the housing through the opening. The rolling shaft RS may be rolled with respect to an imaginary rolling axis AX that extends in the first direction DR1. The rolling axis AX may pass through a central point CP of the rolling shaft RS.

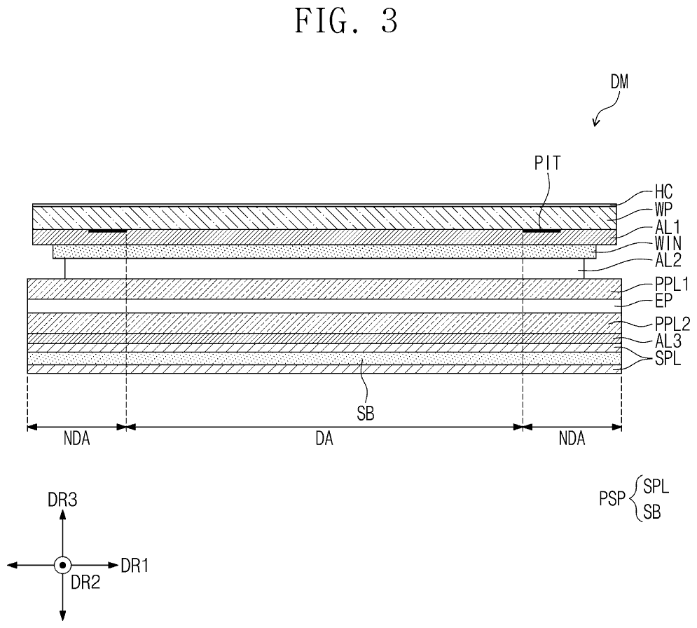

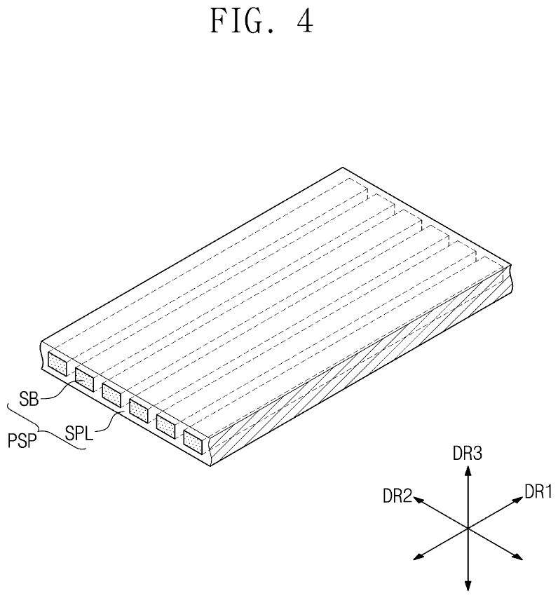

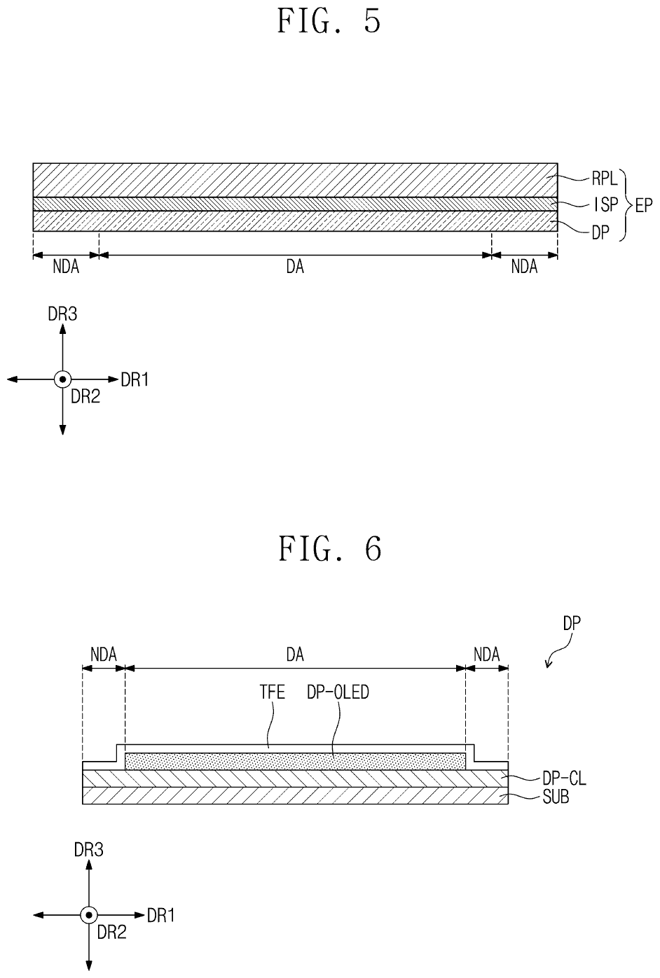

FIG. 3 is a cross-sectional view of a display module according to an embodiment of the disclosure. FIG. 4 is a perspective view of a panel support layer according to an embodiment of the disclosure. FIG. 5 is a cross-sectional view of an electronic panel according to an embodiment of the disclosure. FIG. 6 is a cross-sectional view of a display panel according to an embodiment of the disclosure.

By way of example, FIG. 3 illustrates a cross-section of the display module DM viewed in the second direction DR2.

Referring to FIG. 3, an embodiment of the display module DM may include an electronic panel EP, an upper protective member PPL1, a lower protective member PPL2, a window WIN, a window protective layer WP, a hard coating layer HC, a panel support layer PSP, and first to third adhesion layers AL1 to AL3.

The electronic panel EP may display an image IM (see FIG. 1). The electronic panel EP may include a display panel, an input sensing part, and a reflection preventing layer, and a configuration of the electronic panel EP will be described with reference to FIG. 5 below.

The upper protective member PPL1 may be disposed at an upper portion of the electronic panel EP. The upper protective member PPL1 may protect the electronic panel EP by absorbing an external impact that is applied from a hard coating layer HC toward the electronic panel EP. Accordingly, an impact resistance of the display module DM may be improved.

According to an embodiment of the disclosure, the upper protective member PPL1 may be disposed directly at an upper portion of the electronic panel EP. In the disclosure, disposing one component directly on another component means that no intervening component is disposed between the one component and the other component. That is, when one component is “directly disposed” on another component, it means that one component “contacts” the other component.

In an embodiment, the upper protective member PPL1 may be formed by applying an organic material to an upper portion of the electronic panel EP by using an inkjet printing process. The layers and/or patterns included in the upper protective member PPL1 will be described later.

The lower protective member PPL2 may be disposed at a lower portion of the electronic panel EP. The lower protective member PPL2 may absorb an external impact applied from the hard coating layer HC toward the electronic panel EP or from the panel support layer PSP toward the electronic panel EP to protect the electronic panel EP. Accordingly, an impact resistance of the display module DM may be improved.

According to an embodiment of the disclosure, the lower protective member PPL2 may be disposed directly at a lower portion of the electronic panel EP. Accordingly, an intervening component may not be disposed between the lower protective member PPL2 and the electronic panel EP.

In an embodiment, the lower protective member PPL2 may be formed by applying an organic material to a lower portion of the electronic panel EP by using the Inkjet Printing process. The layers and/or patterns included in the lower protective member PPL2 will be described later. In the display module DM according to an embodiment, one of the upper protective member PPL1 and the lower protective member PPL2 may be omitted.

A window WIN may be disposed on the upper protective member PPL1. The window WIN may protect the electronic panel EP from external scratches. The window WIN may have optically transparent properties. In an embodiment, the window WIN may include glass. However, the disclosure is not limited thereto, and the window WIN may include a synthetic resin film in another embodiment.

A window protective layer WP may be disposed on the window WIN. The window protective layer WP may include a flexible plastic material, such as polyimide or polyethylene terephthalate. The hard coating layer HC may be disposed on an upper portion of the window protective layer WP.

A printing layer PIT may be disposed at a lower portion of the window protective layer WP. The printing layer PIT may be black, but a color of the printing layer PIT is not limited thereto. The printing layer PIT may be adjacent to a periphery of the window protective layer WP. The printing layer PIT may overlap the non-display area NDA.

The panel support layer PSP may be disposed at a lower portion of the lower protective member PPL2. The panel support layer PSP may serve to support the electronic panel EP when the electronic panel EP is rolled on the rolling shaft RS. The panel support layer PSP may include a support layer SPL, and a plurality of support bars SB that is disposed in the support layer SPL.

Referring to FIG. 4, the support bars SB may extend in the first direction DR1, and may be spaced apart along the second direction DR2 in a plan view. When viewed in the first direction DR1, the support bars SB may have a rectangular shape, but the shape of the support bars SB is not limited thereto.

In FIG. 4, the support bars SB disposed in the support layer SPL are illustrated with dotted lines by way of example. The support bars SB may be spaced apart from each other at equal intervals in the second direction DR2, but the interval between the support bars SB is not limited thereto. Opposite ends of the support bars SB, which are opposite to each other, in the first direction DR1 may not be disposed in the support layer SPL, but may be exposed to an outside of the support layer SPL.

The support bars SB may be of a rigid type. In an embodiment, for example, the support bars SB may include metal. The support bars SB may include aluminum, stainless steel, or invar.

The support layer SPL may include an elastic polymer having a specific elastic force. In an embodiment, for example, the support layer SPL may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, and ethylene-vinyl acetate.

The support bars SB may have a greater modulus than the support layer SPL. The support layer SPL may have a modulus in a range of 20 kilopascals (Kpa) to about 20 megapascals (MPa). The support bars SB may have a modulus in a range of 1 gigapascals (GPa) to about 200 GPa. Here, the modulus may be a bulk modulus, elastic module, shear modulus or Young's modulus. In an embodiment, for example, the modulus may be Young's modulus.

The support bars SB having a relatively greater modulus may serve to support the electronic panel EP. The support layer SPL may provide a flat upper surface on the support bars SB. In a case where the support layer SPL is not provided and the support bars SB are disposed under the electronic panel EP, a curve is formed in the electronic panel EP by the support bars SB, and the electronic panel EP may be deformed. In an embodiment, the support bars SB are disposed in the support layer SPL and the support layer SPL provides a flat upper surface under the electronic panel EP, such that deformation of the electronic panel EP may be effectively prevented.

Referring back to FIG. 3, the first adhesion layer AL1 may be disposed between the window protective layer WP and the window WIN. The window protective layer WP and the window WIN may be combined with each other by the first adhesion layer AL1. The first adhesion layer AL1 may cover the printing layer PIT.

The second adhesion layer AL2 may be disposed between the window WIN and the upper protective member PPL1. The window WIN and the upper protective member PPL1 may be combined with each other by the second adhesion layer AL2.

The third adhesion layer AL3 may be disposed between the lower protective member PPL2 and the panel support layer PSP. The lower protective member PPL2 and panel support layer PSP may be combined with each other by the third adhesion layer AL3.

According to an embodiment of the disclosure, separate adhesion layers may be omitted between the electronic panel EP and the upper protective member PPL1 and between the electronic panel EP and the lower protective member PPL2. Accordingly, a slim display module DM may be provided.

The first to third adhesion layers AL1 to AL3 may include a pressure sensitive adhesive (PSA) or an optically clear adhesive (OCA), but the type of adhesive is not limited thereto.

FIG. 5 illustrates a cross section of the electronic panel EP viewed in the second direction DR2.

Referring to FIG. 5, an embodiment of the electronic panel EP may include a display panel DP, an input sensing part ISP that is disposed on the display panel DP, and a reflection preventing layer RPL that is disposed on the input sensing part ISP. The display panel DP may be a flexible display panel. In an embodiment, for example, the display panel DP may include a flexible substrate and a plurality of elements that are disposed on the flexible substrate.

The display panel DP according to an embodiment of the disclosure may be a light emitting display panel, and is not particularly limited. In an embodiment, for example, the display panel DP may be an organic light emitting display panel or an inorganic light emitting display panel. The light emitting layer of the organic light emitting display panel may include an organic light emitting material. The light-emitting layer of the inorganic light-emitting display panel may include quantum dots and quantum rods. Hereinafter, for convenience of description, embodiment where the display panel DP is an organic light emitting display panel will be mainly described.

The input sensing part ISP may include a plurality of sensing parts for sensing an external input. In an embodiment, for example, the input sensing part ISP may sense an external input by using a capacitive method, but the sensing method of the input sensing part ISP is not limited thereto. According to an embodiment, the input sensing part ISP may be disposed directly on the electronic panel EP. Accordingly, the input sensing part ISP may be formed on the electronic panel EP through a continuous process.

The reflection preventing layer RPL may be disposed on the input sensing part ISP. The reflection preventing layer RPL may be disposed directly on the input sensing part ISP when the electronic panel EP is manufactured. The reflection preventing layer RPL may be defined as a film that prevents reflection of external light. The reflection preventing layer RPL may reduce a reflectance of the external light that is input toward the display panel DP.

When the external light that travels toward the display panel DP is reflected from the display panel DP and is provided back to the external user, like a mirror, the user may perceive the external light. In an embodiment, the reflection preventing layer RPL may include a plurality of color filters that display the same color as that of the pixels of the display panel DP to prevent this phenomenon.

The color filters may filter external light with a same color as that of the pixels. In such an embodiment, the external light may not be visible to the user. However, the disclosure is not limited thereto, and the reflection preventing layer RPL may include a phase retarder and/or a polarizer in another embodiment to reduce the reflectance of the external light.

According to an embodiment, the input sensing part ISP may be formed directly on the display panel DP, and the reflection preventing layer RPL may be formed directly on the input sensing part ISP, but according to the disclosure, the embodiment is not limited thereto. In another embodiment, for example, the input sensing part ISP is manufactured separately and attached to the display panel DP by an adhesion layer, and the reflection preventing layer RPL may be manufactured separately and attached to the input sensing part ISP by an adhesion layer.

FIG. 6 is a cross-sectional view of the display panel illustrating the configuration of the display panel illustrated in FIG. 5.

By way of example, FIG. 6 illustrates a cross section of the display panel DP viewed in the second direction DR2.

Referring to FIG. 6, an embodiment of the display panel DP may include a substrate SUB, a circuit element layer DP-CL that is disposed on the substrate SUB, a display element layer DP-OLED that is disposed on the circuit element layer DP-CL, and a thin film encapsulation layer TFE that is disposed on the display element layer DP-OLED.

The substrate SUB may include a display area DA, and a non-display area NDA around the display area DA. The substrate SUB may include a flexible plastic material, such as polyimide. The display element layer DP-OLED may be disposed on the display area DA.

A plurality of pixels may be arranged in the display area DA. Each of the pixels may include a light emitting element that is connected to a transistor that is disposed on the circuit element layer DP-CL and is disposed on the display element layer DP-OLED.

The thin film encapsulation layer TFE may be disposed on the circuit element layer DP-CL to cover the display element layer DP-OLED. The thin film encapsulation layer TFE may include inorganic layers and organic layers between the inorganic layers. The inorganic layers may protect the pixels from moisture/oxygen. The organic layer may protect the pixels from foreign substances, such as dust particles.

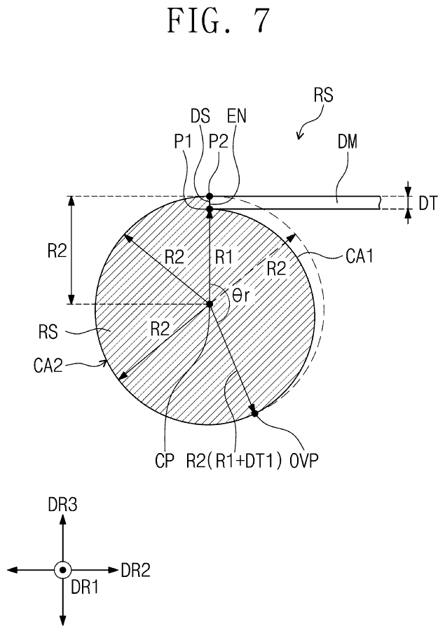

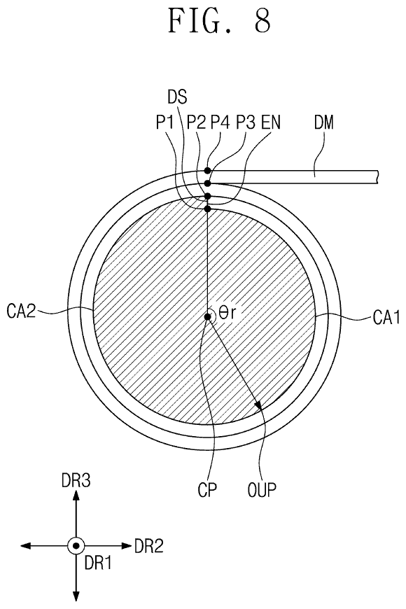

FIG. 7 is a cross-sectional view of a rolling shaft and an unrolled electronic panel according to an embodiment of the disclosure. FIG. 8 is a cross-sectional view of a rolling shaft and a rolled electronic panel according to an embodiment of the disclosure. Particularly, FIG. 7 illustrates a cross-sectional view of the display module DM illustrated in FIG. 3 in an unrolled state on the rolling shaft RS, and FIG. 8 illustrates a cross-sectional view of the display module DM illustrated in FIG. 3 in a rolled state on the rolling shaft RS.

Referring to FIGS. 7 and 8, in an embodiment, the rolling shaft RS may include a first circular arc CA1 and a second circular arc CA2. In such an embodiment, an outer peripheral surface of the rolling shaft RS may include the first circular arc CA1 and the second circular arc CA2. A stepped portion EN may be defined by the first circular arc CAL and the second circular arc CA2.

The rolling shaft RS may have a cylindrical shape that extends in the first direction DR1. The outer peripheral surface of the rolling shaft RS may have a curved surface. The rolling shaft RS may have the stepped portion EN. A portion of the outer peripheral surface of the rolling shaft RS may protrude outward to form the stepped portion EN of the rolling shaft RS. When viewed in the first direction DR1, the stepped portion EN may have a stepped shape (a portion indicated by a dotted line) on the curved outer peripheral surface.

The rolling axis AX (see FIG. 1) that extends in the first direction DR1 may be defined in the rolling shaft RS. A central point CP of the rolling shaft RS may be defined by the rolling axis AX (see FIG. 1). The rolling shaft RS may rotate clockwise or counterclockwise about the rolling axis AX (see FIG. 1).

The first circular arc CAL may be defined as a curve from about zero (0) degree to a reference angle θr with respect to the central point CP. The second circular arc CA2 extends from the first circular arc CA1, and may be defined as a curve from the reference angle θr to about 360 degree with respect to the central point CP. In FIG. 7, about zero (0) degree and about 360 degrees may be defined with respect to an upward direction of the third direction DR3. The reference angle θr may be set to one of angles that are greater than 90 degrees and less than 360 degrees.

A point corresponding to about zero (00 degree of the first circular arc CA1 may be defined as a first point P1. A point corresponding to about 360 degrees of the second circular arc CA2 may be defined as a second point P2. A point corresponding to the reference angle θr may be defined as an overlapping point OVP.

The first circular arc CAL and the second circular arc CA2 may cross each other at the overlapping point OVP corresponding to the reference angle θr. When viewed in the third direction DR3, the first circular arc CAL and the second circular arc CA2 may overlap each other at the first point P1 and the second point P2. A starting point of the first circular arc CAL may be defined as the first point P1, and an ending point of the first circular arc CAL may be defined as the overlapping point OVP. A starting point of the second circular arc CA2 may be defined as the overlapping point OVP, and an ending point of the second circular arc CA2 may be defined as the second point P2.

In the first circular arc CA1, the first point with respect to the central point CP may have a first radius R1. The first circular arc CAL may have a variable radius with respect to the central point CP. In an embodiment, for example, as going from about zero (0) degree to the reference angle θr, a radius of the first circular arc CA1 with respect to the central point CP may gradually increase from the first radius R1 to a second radius R2 that is greater than the first radius R1. Because the radius is variable, the first circular arc CAL may have a variable curvature.

The second circular arc CA2 may have a constant radius with respect to the central point CP. In an embodiment, for example, the second circular arc CA2 may have the second radius R2 with respect to the central point CP from the reference angle θr to about 360 degrees. Because the radius is constant, the second circular arc CA2 may have a constant curvature.

The first circular arc CAL and the second circular arc CA2 in FIG. 7 are defined clockwise from about zero (0) degree, and embodiments of the disclosure may not be limited thereto. In another embodiment, for example, the outer peripheral surface of the rolling shaft RS may be distinguished with respect to the counterclockwise direction. In such an embodiment, along the counterclockwise direction, the outer peripheral surface of the rolling shaft RS may be divided into the first circular arc and the second circular arc with respect to the overlapping point OVP. Accordingly, the first circular arc may be the second circular arc CA2 illustrated in FIG. 7, and the second circular arc may be the first circular arc CA1 illustrated in FIG. 7. Accordingly, with respect to the counterclockwise direction, the radius of the first circular arc may be constant, and the radius of the second circular arc may be variable (for example, may be decreased).

A distance between the first point P1 and the second point P2 may be defined as a spacing distance DT. The spacing distance DT may be defined as a width of the stepped portion EN in the third direction DR3. The second radius R2 may be set to a sum of the spacing distance DT and the first radius R1. That is, according to an embodiment of the disclosure, the stepped portion EN may be defined by a difference between the second radius R2 at about 360 degrees and the first radius R1 at about zero (0) degree.

The first point P1 and the second point P2 are spaced apart from each other, and the second point P2 may be disposed outside the first point P1 and connected to the first point P1. A portion that connects the first point P1 and the second point P2 may be defined as the stepped portion EN of the rolling shaft RS.

According to an embodiment of the disclosure, the spacing distance DT of the stepped portion EN may be similar to a thickness of the display module DM. In an embodiment, for example, a difference (means a difference expressed as an absolute value) between the spacing distance DT and the thickness of the display module DM may be set to about 5% or less of the spacing distance DT. Ideally, the thickness of the display module DM may be equal to the spacing distance DT.

A side surface D-S of the display module DM may be coupled to the stepped portion EN. The side surface D-S of the display module DM may be coupled to the stepped portion EN of the rolling shaft RS through a separate adhesion layer or fastening member.

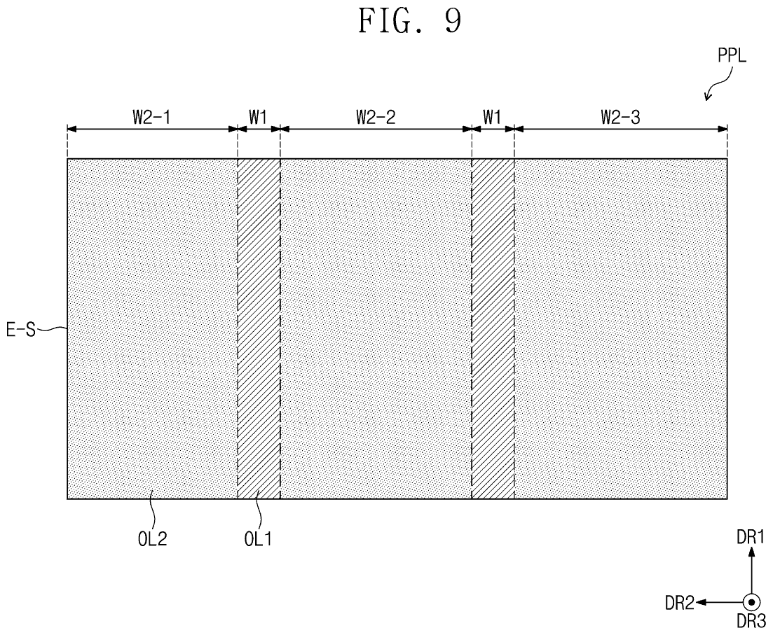

Referring to FIG. 8, when the rolling shaft RS is rotated counterclockwise and the display module DM is rolled, first to fourth points P1, P2, P3, and P4 that overlap a portion, at which the stepped portion EN and the side surfaces DS of the display module DM are coupled to each other may be formed in the display module DM. As the rolling shaft RS is rotated clockwise, a permanent crease may occur at, among the upper and lower portions of the display module DM, a portion that overlaps the first to fourth points P1, P2, P3, and P4 when the display module DM is released from the rolling shaft RS. Accordingly, improvement in a surface quality of the display module DM is desired. Hereinafter, referring to FIGS. 9 to 20, embodiments of a display module, in which a surface quality may be improved by reducing the crease at the first to fourth points P1, P2, P3, and P4 will be described.

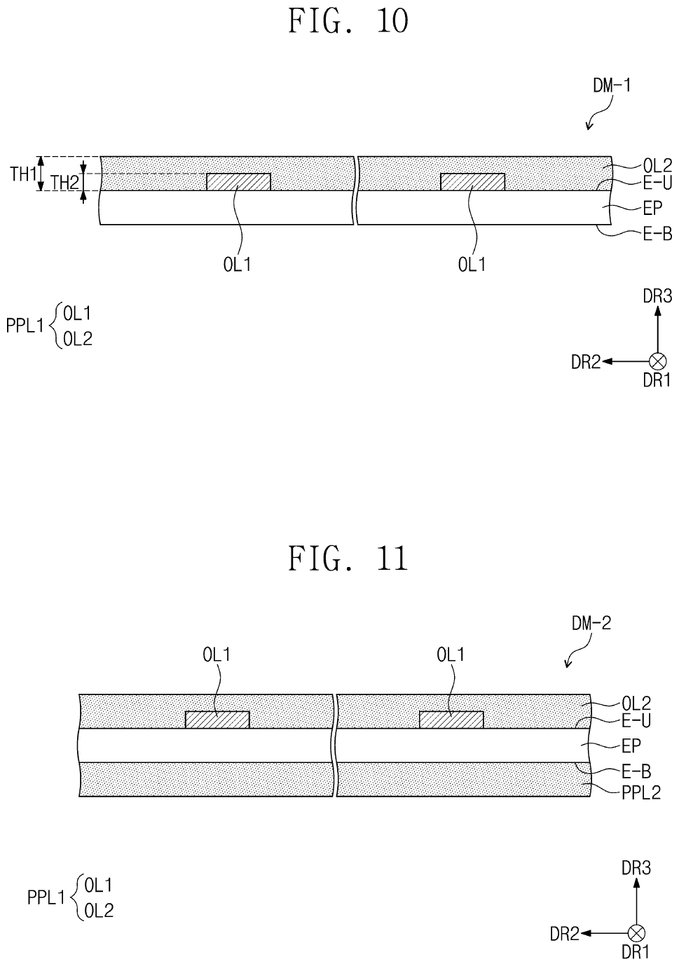

FIG. 9 is a plan view of a protective member according to an embodiment of the disclosure. FIGS. 10 to 20 are cross-sectional views of an electronic panel in an unrolled state according to an embodiment of the disclosure. In FIGS. 9 to 20, the same/similar reference numerals are used for components that are the same/similar to those described in FIGS. 1 to 8, and any repetitive detailed description thereof will be omitted.

Referring to FIG. 9, a protective member PPL according to an embodiment may include protective patterns OL1 and a protective layer OL2. In such an embodiment, the protective member PPL may correspond to at least one selected from the upper protective member PPL1 and the lower protective member PPL2 described in FIG. 3.

The protective patterns OL1 may extend along the first direction DR1, and may be arranged to be spaced apart from each other along the second direction DR2 in a plan view. Herein, a plan view may be a view in an unrolled state viewed in the third direction DR3. According to an embodiment of the disclosure, the protective patterns OL1 may overlap the first to fourth points P1, P2, P3, and P4 (see FIG. 8) in a rolled state of the display module DM (see FIG. 8) on the rolling shaft RS (see FIG. 8). FIG. 9 illustrates two protective patterns OL1 on a plane, but the disclosure is not limited thereto, and the number of the protective patterns may be variable depending on the number of rotations of the display module DM (see FIG. 8) on the rolling shaft RS (see FIG. 8).

The protective layer OL2 may cover the protective patterns OL1. In an embodiment, for example, as illustrated in FIG. 3, where the protective member PPL (corresponding to the upper protective member PPL1) is disposed at an upper portion of the electronic panel EP, lower portions of the protective patterns OL1 may contact an upper portion of the electronic panel EP, and the protective layer OL2 may cover an upper portion of the electronic panel EP and an upper portion of the protective patterns OL1.

According to another embodiment, where the protective member PPL (corresponding to the lower protective member PPL2) is disposed at a lower portion of the electronic panel EP, an upper portion of the protective patterns OL1 may contact a lower portion of the electronic panel EP, the protective layer OL2 may cover lower portions of the electronic panel EP and a lower portion of the protective patterns OL1. However, the disclosure is not limited thereto, and the protective patterns OL1 may not contact an upper portion/rear side of the electronic panel EP, and may be disposed in an interior of protective layer OL2. In such an embodiment, the upper portion/rear side of the electronic panel EP may contact only the protective layer OL2.

A first width W1 of each of the protective patterns OL1 in the first direction DR1 may be in a range of about 20 millimeters (mm) to about 60 mm. A distance from one side surface E-S of, among the protective layers OL2, a protective layer OL2 to one side surface of any one protective pattern OL1 may be defined as a first second width (hereinafter, will be referred to as “(2-1)-th width”) W2-1, a distance from an opposite side surface of the any one protective pattern OL1 to another protective pattern OL1 may be defined as a second second width (hereinafter, will be referred to as “(2-2)-th width”) W2-2, and a distance from an opposite side surface of the other protective pattern OL1 to an opposite side surface (end) of the protective member PPL may be defined as a third second width (hereinafter, will be referred to as “(2-3)-th width”) W2-3. One side surface E-S of the protective layer OL2 may correspond to a portion of the side surface D-S of the display module DM described in FIG. 8. According to an embodiment, the (2-2)-th width W2-2 may be greater than the (2-1)-th width W2-1 and be smaller than the (2-3)-th width W2-3.

According to an embodiment of the disclosure, a modulus of the protective patterns OL1 may be different from a modulus of the protective layer OL2. In an embodiment, for example, the modulus of the protective patterns OL1 may be in a range of about 3 GPa to about 20 GPa, and the modulus of the protective layer OL2 may be in a range f about 0.5 GPa to about 2.5 GPa.

According to an embodiment of the disclosure, the protective patterns OL1 and the protective layer OL2 may include different organic materials from each other. In an embodiment, for example, the protective patterns OL1 may include a polyhedral oligomeric silsesquioxane (POSS)-based material, and the protective layer OL2 may include an acryl-based material. The protective patterns OL1 and the protective layer OL2 may be directly coated on upper and lower portions of the electronic panel EP through an inkjet printing process.

In an embodiment, as described above, the protective patterns OL1 may overlap the first to fourth points P1, P2, P3, and P4 (see FIG. 8) in a rolled state of the display module DM (see FIG. 8) on the rolling shaft RS (see FIG. 8). According to an embodiment of the disclosure, because the protective patterns OL1 having relatively large modulus are disposed locally on the protective layer OL2, a crease may be effective prevented from occurring at a portion of the display module DM, which overlaps the first to fourth points P1, P2, P3, and P4 (see FIG. 8) even through the display module DM (see FIG. 8) is attached to the rolling shaft RS (see FIG. 8) and is repeatedly rolled. Accordingly, a damage to the electronic panel EP may be effectively prevented, and a display device EA having an improved reliability (see FIG. 1) may be provided.

FIGS. 10 to 20 are cross-sectional views of the protective member and an area of the electronic panel. FIGS. 10 to 20 illustrate only, among the components of the display module DM described in FIG. 3, the electronic panel EP and the protective member, and other components are omitted.

Referring to FIG. 10, a display module DM-1 according to an embodiment may include an electronic panel EP and an upper protective member PPL1. The electronic panel EP may include an upper portion E-U and a lower portion E-B. In such an embodiment, the upper protective member PPL1 may be directly disposed on the upper portion E-U of the electronic panel EP.

The upper protective member PPL1 may include protective patterns OL1 and a protective layer OL2. The protective patterns OL1 may extend along the first direction DR1, and be arranged to be spaced apart from each other along the second direction DR2 in a plan view. The protective patterns OL1 may contact the upper portion E-U of the electronic panel EP. The protective layer OL2 may cover the upper portion E-U and the protective patterns OL1 of the electronic panel EP.

According to an embodiment, as shown in FIG. 10, the protective member may not be disposed at the lower portion E-B of the electronic panel EP, and the third adhesion layer AL3 and the panel support layer PSP described in FIG. 3 may be disposed at the lower portion E-B of the electronic panel EP.

According to an embodiment, a first thickness TH1 of the protective layer OL2 may be greater than a second thickness TH2 of the protective patterns OL1. In an embodiment, for example, The first thickness TH1 may be in a range of about 10 micrometers (μm) to about 100 μm, and the second thickness TH2 may be in a range of about 1 μm to about 50 μm. Accordingly, upper surfaces of the protective patterns OL1 may be covered by the protective layer OL2.

Referring to FIG. 11, a display module DM-2 according to an embodiment may include an electronic panel EP and an upper protective member PPL1. The display module DM-2 according to an embodiment may further include a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include protective patterns OL1 and a protective layer OL2. The protective patterns OL1 may extend along the first direction DR1, and be arranged to be spaced apart from each other along the second direction DR2 in a plan view. The protective patterns OL1 may contact the upper portion E-U of the electronic panel EP. The protective layer OL2 may cover the upper portion E-U and the protective patterns OL1 of the electronic panel EP.

According to an embodiment, as shown in FIG. 11, the lower protective member PPL2 may include a same material as that of the protective layer OL2. In an embodiment, for example, the protective layer OL2 and the lower protective member PPL2 may include an acryl-based material. Moduli of the protective layer OL2 and the lower protective member PPL2 may be the same as each other. The protective patterns OL1 may include a polyhedral oligomeric silsesquioxane (POSS)-based material.

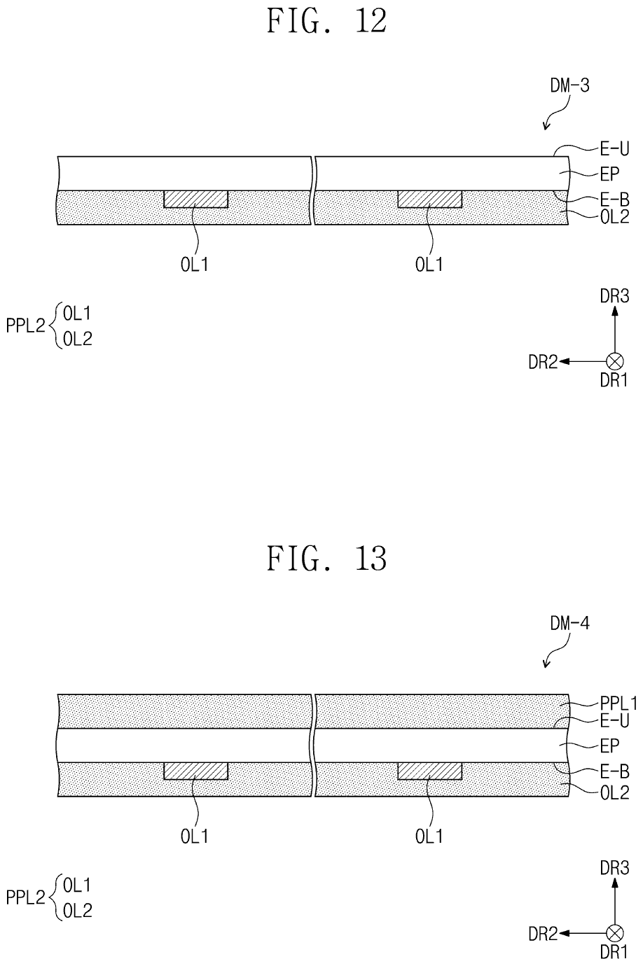

Referring to FIG. 12, a display module DM-3 according to an embodiment may include an electronic panel EP and an upper protective member PPL2. The electronic panel EP may include an upper portion E-U and a lower portion E-B. In such an embodiment, the lower protective member PPL2 may be directly disposed on the lower portion E-B of the electronic panel EP.

The lower protective member PPL2 may include protective patterns OL1 and a protective layer OL2. The protective patterns OL1 may extend along the first direction DR1, and be arranged to be spaced apart from each other along the second direction DR2 in a plan view. The protective patterns OL1 may contact the lower portion E-U of the electronic panel EP. The protective layer OL2 may cover the lower portion E-B and the protective patterns OL1 of the electronic panel EP. According to an embodiment, as shown in FIG. 12, the protective member may not be disposed at the upper portion E-U of the electronic panel EP, and the second adhesion layer AL2 and the window WIN described in FIG. 3 may be disposed at the upper portion E-U of the electronic panel EP.

Referring to FIG. 13, a display module DM-4 according to an embodiment may include an electronic panel EP and an upper protective member PPL2. The display module DM-4 according to an embodiment may further include an upper protective member PPL1. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The lower protective member PPL2 may include protective patterns OL1 and a protective layer OL2. The protective patterns OL1 may extend along the first direction DR1, and be arranged to be spaced apart from each other along the second direction DR2 in a plan view. The protective patterns OL1 may contact the lower portion E-U of the electronic panel EP. The protective layer OL2 may cover the lower portion E-B and the protective patterns OL1 of the electronic panel EP.

According to an embodiment, as shown in FIG. 13, the upper protective member PPL1 may include the same material as that of the protective layer OL2. In an embodiment, for example, the protective layer OL2 and the upper protective member PPL1 may include an acryl-based material. Moduli of the protective layer OL2 and the upper protective member PPL1 may be the same as each other. The protective patterns OL1 may include a polyhedral oligomeric silsesquioxane (POSS)-based material.

Referring to FIG. 13, a display module DM-5 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may extend along the first direction DR1, and be arranged to be spaced apart from each other along the second direction DR2 in a plan view. The upper protective patterns OL1-U may contact the upper portion E-U of the electronic panel EP. The upper protective layer OL2-U may cover the upper portion E-U and the upper protective patterns OL1-U.

The lower protective member PPL2 may include lower protective patterns OL1-B and a lower protective layer OL2-B. The lower protective patterns OL1-B may extend along the first direction DR1, and may be arranged to be spaced apart from each other along the second direction DR2 in a plan view. The lower protective patterns OL1-B may contact the lower portion E-B of the electronic panel EP. The lower protective layer OL2-B may cover the lower portion E-B and the lower protective patterns OL1-B of the electronic panel EP.

According to an embodiment, as shown in FIG. 14, the upper protective layer OL2-U and the lower protective layer OL2-B may include a same material as each other. In an embodiment, for example, each of the upper protective layer OL2-U and the lower protective layer OL2-B may include an acryl-based material. The upper protective layer OL2-U and the lower protective layer OL2-B may have a same modulus as each other. In an embodiment, for example, each of the upper protective patterns OL1-U and the lower protective patterns OL1-B may include a polyhedral oligomeric silsesquioxane (POSS)-based material. The upper protective patterns OL1-U and the lower protective patterns OL1-B may have a same modulus as each other.

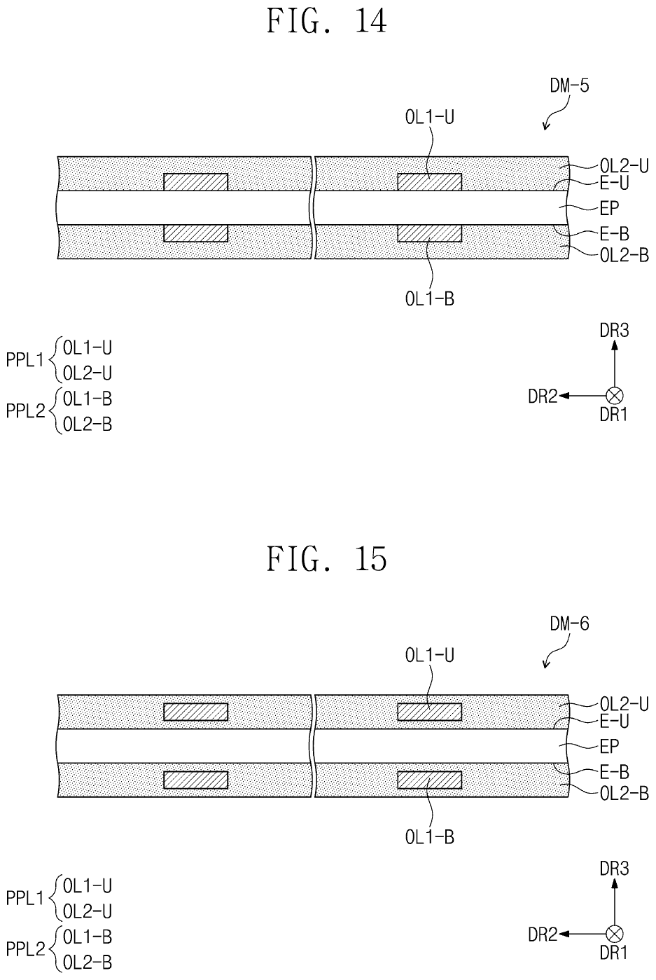

Referring to FIG. 15, a display module DM-6 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

In such embodiment, the protective members PPL1 and PPL2 are substantially the same as those described above with reference to FIG. 14. Accordingly, for convenience of description, differences from the protective members PPL1 and PPL2 in FIG. 14 will be mainly described.

The upper protective member PPL1 may include upper protective patterns OL1-U and an upper protective layer OL2-U. The upper protective patterns OL1-U may extend along the first direction DR1, and be arranged to be spaced apart from each other along the second direction DR2 in a plan view.

According to an embodiment, as shown in FIG. 15, the upper protective patterns OL1-U may not contact the electronic panel EP. The upper protective patterns OL1-U may be disposed in an interior of the upper protective layer OL2-U to be spaced apart from the electronic panel EP.

The lower protective member PPL2 may include lower protective patterns OL1-B and a lower protective layer OL2-B. The lower protective patterns OL1-B may extend along the first direction DR1, and may be arranged to be spaced apart from each other along the second direction DR2 in a plan view.

According to an embodiment, as shown in FIG. 15, the lower protective patterns OL1-B may not contact the electronic panel EP. The lower protective patterns OL1-B may be disposed in an interior of the lower protective layer OL2-B to be spaced apart from the electronic panel EP.

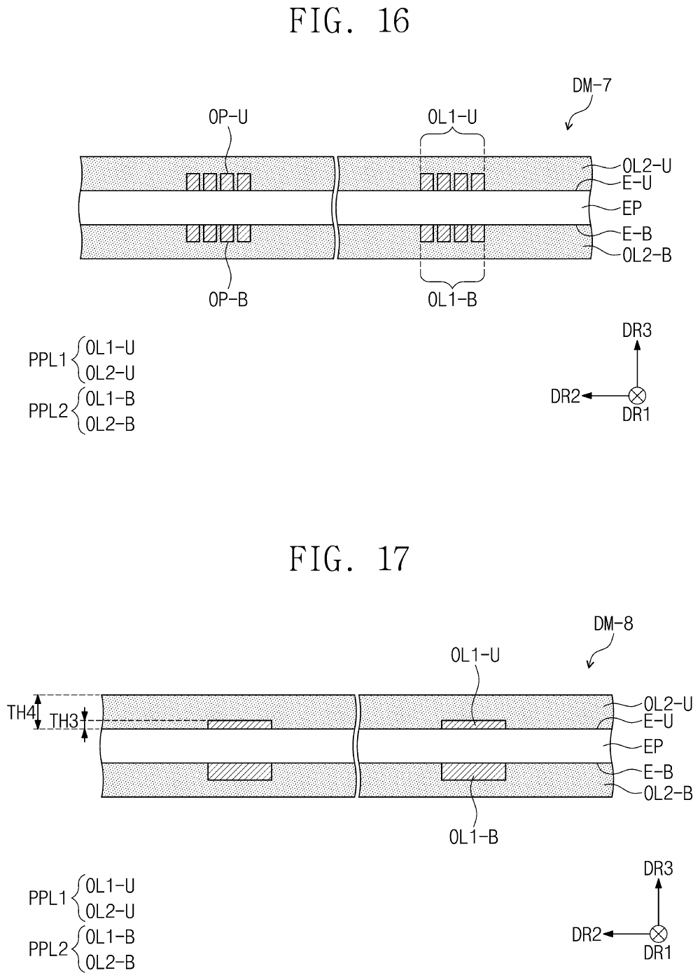

Referring to FIG. 16, a display module DM-7 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may contact the upper portion E-U of the electronic panel EP. The upper protective layer OL2-U may cover the upper portion E-U and the upper protective patterns OL1-U.

According to an embodiment, as shown in FIG. 16, each of the upper protective patterns OL1-U may include a plurality of upper patterns OP-U. The upper patterns OP-U may extend along the first direction DR1, and the upper patterns OP-U may be arranged to be spaced apart from each other along the second direction DR2 in a plan view. An upper protective layer OL2-U may be disposed between adjacent upper patterns OP-U along the second direction DR2.

The lower protective member PPL2 may include lower protective patterns OL1-B and a lower protective layer OL2-B. The lower protective patterns OL1-B may contact the lower portion E-B of the electronic panel EP. The lower protective layer OL2-B may cover the lower portion E-B and the lower protective patterns OL1-B of the electronic panel EP.

According to an embodiment, as shown in FIG. 16, each of the lower protective patterns OL1-B may include a plurality of lower patterns OP-B. The lower patterns OP-B may extend along the first direction DR1, and the lower patterns OP-B may be arranged to be spaced apart from each other along the second direction DR2 in a plan view. An upper protective layer OL2-U may be disposed between adjacent lower patterns OP-B along the second direction DR2.

Referring to FIG. 17, a display module DM-8 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may contact the upper portion E-U of the electronic panel EP. The upper protective layer OL2-U may cover the upper portion E-U and the upper protective patterns OL1-U.

The lower protective member PPL2 may include lower protective patterns OL1-B and a lower protective layer OL2-B. The lower protective patterns OL1-B may contact the lower portion E-B of the electronic panel EP. The lower protective layer OL2-B may cover the lower portion E-B and the lower protective patterns OL1-B of the electronic panel EP.

According to an embodiment, as shown in FIG. 17, a third thickness TH3 of the upper protective patterns OL1-U and a fourth thickness TH4 of the lower protective patterns OL1-B may be different from each other. In an embodiment, for example, the third thickness TH3 may be less than the fourth thickness TH4. However, the disclosure is not limited thereto, and the third thickness TH3 may be greater than the fourth thickness TH4 in another embodiment.

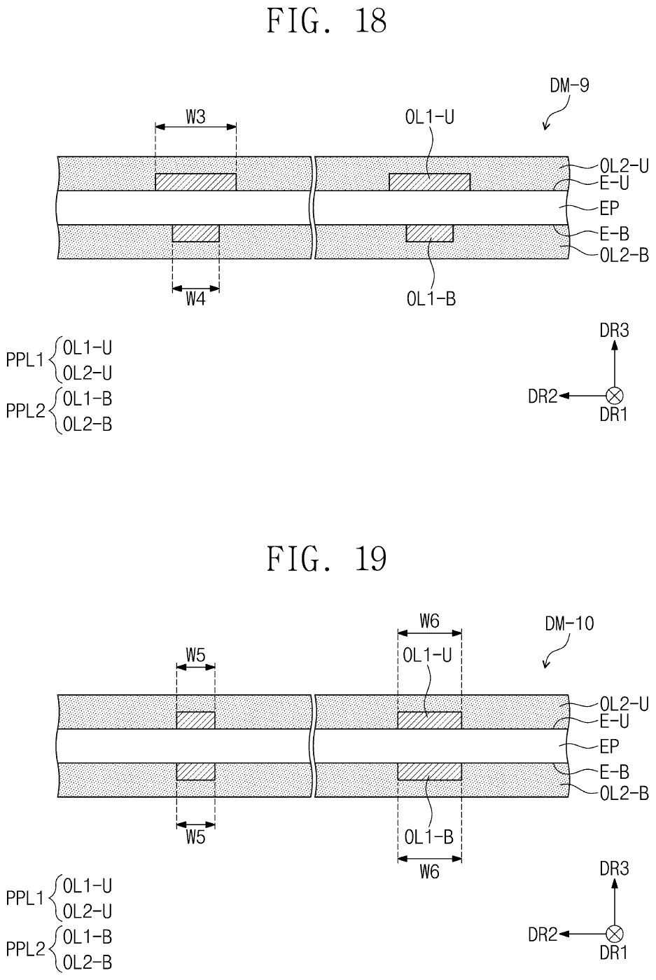

Referring to FIG. 18, a display module DM-9 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may contact the upper portion E-U of the electronic panel EP. The upper protective layer OL2-U may cover the upper portion E-U and the upper protective patterns OL1-U.

The lower protective member PPL2 may include lower protective patterns OL1-B and a lower protective layer OL2-B. The lower protective patterns OL1-B may contact the lower portion E-B of the electronic panel EP. The lower protective layer OL2-B may cover the lower portion E-B and the lower protective patterns OL1-B of the electronic panel EP.

According to an embodiment, as shown in FIG. 19, a third width W3 of the upper protective patterns OL1-U and a fourth width W4 of the lower protective patterns OL1-B may be different from each other in the second direction DR2. In an embodiment, for example, the third width W3 may be greater than the fourth width W4. However, the disclosure is not limited thereto, and the third width W3 may be less than the fourth width W4 in another embodiment.

Referring to FIG. 19, a display module DM-10 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may contact the upper portion E-U of the electronic panel EP. The upper protective layer OL2-U may cover the upper portion E-U and the upper protective patterns OL1-U of the electronic panel EP.

The lower protective member PPL2 may include lower protective patterns OL1-B and a lower protective layer OL2-B. The lower protective patterns OL1-B may contact the lower portion E-B of the electronic panel EP. The lower protective layer OL2-B may cover the lower portion E-B and the lower protective patterns OL1-B of the electronic panel EP.

Each of the upper protective patterns OL1-U and the upper protective patterns OL1-U may include a first pattern that is adjacent to the side surface D-S of the display module DM described in FIG. 8, and a second pattern that is spaced apart from the side surface D-S further than the first pattern.

The fifth width W5 of the first pattern and the sixth width W6 of the second pattern may be different from each other. In an embodiment, for example, the fifth width W5 may be greater than the sixth width W6. However, the disclosure is not limited thereto, and the fifth width W5 may be less than the sixth width W6 in another embodiment.

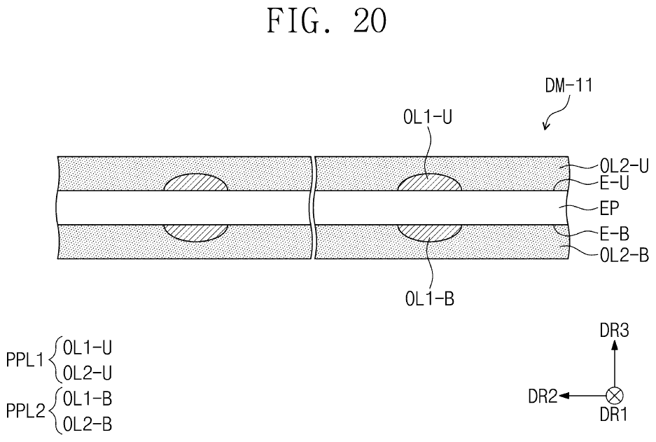

Referring to FIG. 20, a display module DM-11 according to an embodiment may include an electronic panel EP, an upper protective member PPL1, and a lower protective member PPL2. The electronic panel EP may include an upper portion E-U and a lower portion E-B. In such an embodiment, the upper protective member PPL1 may be disposed directly on the upper portion E-U of the electronic panel EP, and the lower protective member PPL2 may be disposed directly on the lower portion E-B of the electronic panel EP.

The upper protective member PPL1 may include upper protective patterns OL1-U and an upper protective layer OL2-U. The upper protective patterns OL1-U may contact the upper portion E-U of the electronic panel EP. The upper protective layer OL2-U may cover the upper portion E-U and the upper protective patterns OL1-U.

According to an embodiment, as shown in FIG. 20, the upper protective patterns OL1-U may have a convex shape that protrudes in a direction that faces the upper portion E-U from the lower portion E-B of the electronic panel EP.

The lower protective member PPL2 may include lower protective patterns OL1-B and a lower protective layer OL2-B. The lower protective patterns OL1-B may contact the lower portion E-B of the electronic panel EP. The lower protective layer OL2-B may cover the lower portion E-B and the lower protective patterns OL1-B of the electronic panel EP.

The upper protective patterns OL1-B according to an embodiment may have a convex shape that protrudes in a direction that faces the lower portion E-B from the upper portion E-U of the electronic panel EP.

According to embodiments of the disclosure, the protective member attached to the upper or lower portion of the rollable display module includes components having different moduli from each other, such that a crease may be effectively prevented from occurring in some parts of the electronic panel even through the rolling is repeated. Accordingly, a display device with an improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display module including an electronic panel, and a protective member disposed on an upper portion or a lower portion of the electronic panel, which are opposite to each other; and
a rolling shaft extending in a first direction in a way such that the display module is rolled thereon, wherein a stepped portion, to which a side surface of the display module is coupled, is defined in the rolling shaft,
wherein the protective member includes:
protective patterns each extending along the first direction and spaced apart from each other along a second direction crossing the first direction in a plan view; and
a protective layer covering the electronic panel and the protective patterns, and
wherein at least one selected from the protective patterns overlaps the stepped portion in a state, in which the display module is rolled on the rolling shaft.

2. The electronic device of claim 1, wherein a modulus of the protective patterns and a modulus of the protective layer are different from each other.

3. The electronic device of claim 2, wherein the modulus of the protective patterns is in a range of about 3 GPa to about 20 GPa, and
wherein the modulus of the protective layer is in a range of about 0.5 GPa to about 2.5 GPa.

4. The electronic device of claim 1, wherein the protective patterns include a polyhedral oligomeric silsesquioxane-based material, and
wherein the protective layer includes an acrylic-based material.

5. The electronic device of claim 1, wherein a thickness of the protective patterns is in a range of about 1 μm to about 50 μm, and
wherein a thickness of the protective layer is in a range of about 10 μm to about 100 μm.

6. The electronic device of claim 1, wherein a width of the protective patterns is in a range of about 20 mm to about 60 mm.

7. The electronic device of claim 1, wherein the rolling shaft includes a first circular arc being a curve from about zero (0) degree to a reference angle with respect to a central point of the rolling shaft, and a second circular arc being a curve from the reference angle to about 360 degrees with respect to the central point, on a cross-section being perpendicular to the first direction,
wherein the first circular arc has a first radius varying with respect to the central point,
wherein the second circular arc has a second radius, which is constant, with respect to the central point, and
wherein the stepped portion is defined by a difference between the second radius at about 360 degrees and the first radius at about zero (0) degree.

8. The electronic device of claim 7, wherein the difference between the second radius at about 360 degrees and the first radius at about zero (0) degree is the same as a thickness of the side surface of the display module.

9. The electronic device of claim 1, wherein the protective member is disposed on the upper portion of the electronic panel, and
wherein the protective patterns and the protective layer contact the upper portion.

10. The electronic device of claim 9, further comprising:
a lower protective member contacting the lower portion of the electronic panel, wherein the lower protective member includes a same material as a material of the protective layer.

11. The electronic device of claim 9, further comprising:
a lower protective member disposed on the lower portion of the electronic panel,
wherein the lower protective member includes:
lower protective patterns each extending along the first direction and spaced apart from each other along a second direction crossing the first direction in the plan view; and
a lower protective layer covering the lower protective patterns and the lower portion, and
wherein the lower protective patterns overlap the protective patterns.

12. The electronic device of claim 11, wherein a thickness of the protective patterns is less than a thickness of the lower protective patterns.

13. The electronic device of claim 11, wherein a width of the protective patterns is greater than a width of the lower protective patterns.

14. The electronic device of claim 11, wherein the protective patterns have a shape convex from the lower portion in a direction facing the upper portion, and the lower protective patterns have a shape convex from the upper portion in a direction facing the lower portion, on a cross-section.

15. The electronic device of claim 1, wherein the protective patterns include a first pattern adjacent to the side surface of the display module and a second pattern spaced apart from the side surface of the display module further than the first pattern, and
wherein a width of the second pattern is greater than a width of the first pattern.

16. The electronic device of claim 1, wherein the protective patterns are disposed in an interior of the protective layer not to contact the electronic panel.

17. The electronic device of claim 1, wherein each of the protective patterns includes patterns extending in the first direction and spaced apart from each other along the second direction in the plan view, and
wherein a portion of the protective layer is disposed between adjacent ones of the patterns along the second direction.

18. The electronic device of claim 1, wherein the protective patterns and the protective layer contact the lower portion of the electronic panel.

19. The electronic device of claim 18, further comprising:
an upper protective member contacting an upper portion opposite to the lower portion, wherein the upper protective member includes a same material as a material of the protective layer.

20. The electronic device of claim 1, further comprising:
a panel support layer disposed on the lower portion of the electronic panel,
wherein the panel support layer includes a support layer, and support bars each extending along the first direction and spaced apart from each other along the second direction in the plan view, and
wherein the support bars are disposed in an interior of the support layer.
